(19) United States
(12) Patent Application Publication
(10) Pub. No.: US 2014/0055977 A1
(43) Pub. Date: Feb. 27, 2014

(54) ELECTRICAL ACTUATOR FOR VARIABLE GEOMETRY TURBOCHARGER

(71) Applicant: Mando Corporation, Pyeongtaek-si (KR)

(72) Inventor: Jin Ra KIM, Hwaseong-si (KR)

(73) Assignee: MANDO CORPORATION, Pyeongtaek-si (KR)

(21) Appl. No.: 13/971,385

(22) Filed: Aug. 20, 2013

(30) Foreign Application Priority Data
Aug. 21, 2012 (KR) 10-2012-0091402
Jul. 26, 2013 (KR) 10-2013-0088988

(51) Int. Cl. H05K 9/00

(52) U.S. Cl. CPC H05K 9/0037
USPC 361/818

(57) ABSTRACT

Provided is an electrical actuator for a variable geometry turbocharger. A lever is disposed outside a housing and is connected to a bottom end of an output shaft of a deceleration device, a ground structure is installed between a printed circuit board and a housing protrusion so as to prevent an electromagnetic interference (EMI) from occurring, a part of insertion parts is inserted in and is fixed to the printed circuit board, an end of an elastic part is mounted on the housing protrusion so that the ground structure can be maintained by an elastic force.

### CROSS-REFERENCE TO RELATED APPLICATION

This application claims priority to and the benefit of Korean Patent Application No. 10-2012-0091402 filed on Aug. 21, 2012 and Korean Patent Application No. 10-2013-0088988 filed on Jul. 26, 2013, the disclosure of which is incorporated herein by reference in its entirety.

### BACKGROUND

1. Field of the Invention

The present invention relates to an electrical actuator for a variable geometry turbocharger, and more particularly, to an electrical actuator for a variable geometry turbocharger, whereby an electronic control device is connected to a housing or a housing protrusion via a ground structure so that an electromagnetic interference (EMI) can be effectively eliminated.

2. Discussion of Related Art

Turbochargers each include an impeller that is rotated by a pressure of an exhaust gas at a high speed and pressurizes air, a turbine that converts thermal energy of the exhaust gas into a rotational force, a floating bearing that supports a turbine shaft, a super pressure relief that prevents a super pressure from increasing over a regulation, an intercooler that cools supercharged air, and a knocking prevention structure in which an injection time is adjusted to prevent the occurrence of knocking.

In turbochargers, a delay time (turbocharger lag) occurs until a throttle valve is opened and the turbocharger supplies an additional power, and variable geometry turbochargers have been developed so as to minimize the delay time.

Variable geometry turbochargers can be largely classified into variable nozzle turbochargers and variable area turbochargers. In variable nozzle turbochargers, rotating blades are attached to the periphery of a turbo wheel, and an actuator controlled by an electronic control device adjusts positions of the rotating blades. That is, the rotating blades are partially opened at a low engine velocity not to generate an unnecessary super pressure such that an exhaust resistance is reduced.

In variable area turbochargers, an electronic control device controls one or more rotating blades disposed at a turbine inlet and controls the velocity of gas so as to control the velocity of a turbine. That is, rotating blades during acceleration are controlled to increase the velocity of the exhaust gas, and a super pressure is rapidly supplied.

However, in such a configuration, an electromagnetic interference (EMI) occurs, which causes lowered quality of variable geometry turbochargers. Thus, an additional structure for eliminating EMI, such as a filter circuit, and an additional fixing unit for fixing the additional structure in the housing are required. As a result, space in the housing cannot be effectively utilized, and the configuration is vulnerable to vibration of a vehicle, and additional costs are required to manufacture a product and thus production cost increases.

### SUMMARY OF THE INVENTION

The present invention is directed to an electrical actuator for a variable geometry turbocharger, whereby an electronic control device of the electrical actuator for the variable geometry turbocharger is connected to a housing or a housing protrusion via a ground structure so that an electromagnetic interference (EMI) can be effectively eliminated.

According to an aspect of the present invention, there is provided an electrical actuator for a variable geometry turbocharger, including: a lever that is disposed outside a housing and is connected to a bottom end of an output shaft of a deceleration device; and a ground structure that is installed between a printed circuit board and a housing protrusion so as to prevent an electromagnetic interference (EMI) from occurring.

The ground structure may include a flat panel part, insertion parts that are upwardly refracted from the flat panel part and are inserted into the printed circuit board, and an elastic part that extends downwardly from the flat panel part and having elasticity, wherein a part of the insertion parts is inserted into and is fixed to the printed circuit board, and an end of the elastic body is mounted on a housing protrusion so that the ground structure is able to be maintained by an elastic force.

The ground structure may be one of an elastic body and a group clip, and the elastic body may be one of a leaf spring and a compression spring.

The housing may further include an insertion hole in which the output shaft is inserted, and housing protrusions may protrude from a periphery of the insertion hole and may contact an extension part of an output gear so as to limit a rotation angle of the output gear.

The electrical actuator for the variable geometry turbocharger may further include a restoring spring that is connected to the output gear of the deceleration device and causes the lever to be moved to an initial position of the lever when a supply of power is stopped.

The restoring spring may be connected to the output gear and may cause the lever to be moved to the initial position of the lever when the supply of power is stopped, and a top end of the restoring spring may be hung in a hanging part of the output gear, and a bottom end of the restoring spring may be fixed to a bottom of the housing.

The restoring spring may be a torsion spring.

The housing may further include a magnet installed at one side of the output shaft and a sensor, and the sensor may measure a rotation angle of the output gear using a change of flux of the magnet.

As described above, in an electrical actuator for a variable geometry turbocharger according to the present invention, an electronic control device for controlling an operating angle of a lever protrudes from the periphery of an insertion hole of a housing through a ground structure and is connected to a housing protrusion that contacts an extension part of an output gear and limits a rotation angle of the output gear so that an electromagnetic interference (EMI) can be effectively eliminated.

The effect of the present invention is not limited to the above-mentioned matters, and other unmentioned effects would be clearly understood by one of skilled in the art from the following description.

### BRIEF DESCRIPTION OF THE DRAWINGS

The above and other objects, features and advantages of the present invention will become more apparent to those of ordinary skill in the art by describing in detail exemplary embodiments thereof with reference to the accompanying drawings, in which:

FIG. 1 is an exploded perspective view illustrating an electrical actuator for a variable geometry turbocharger according to an embodiment of the present invention;

FIG. 2 is a cross-sectional view illustrating the electrical actuator for the variable geometry turbocharger illustrated in FIG. 1; and

FIG. 3 is a partial perspective view illustrating the electrical actuator for the variable geometry turbocharger of FIG. 1.

### DETAILED DESCRIPTION OF EXEMPLARY EMBODIMENTS

Exemplary embodiments of an electrical actuator for a variable geometry turbocharger according to the present invention will be described in detail below with reference to the accompanying drawings. First, when adding reference numerals to elements of the drawings, it will be noted that, even when like elements are indicated in different drawings, like elements have like symbols as possible. Also, in the description of the present invention, if it is determined that a detailed description of commonly-used configurations or functions related to the invention may unnecessarily obscure the subject matter of the invention, the detailed description will be omitted.

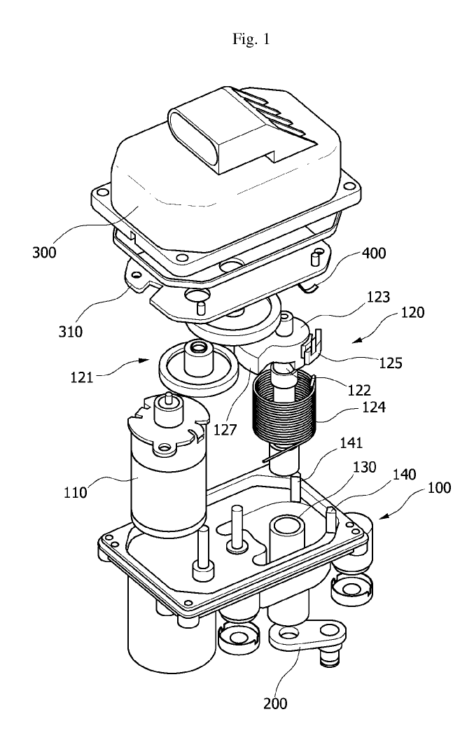

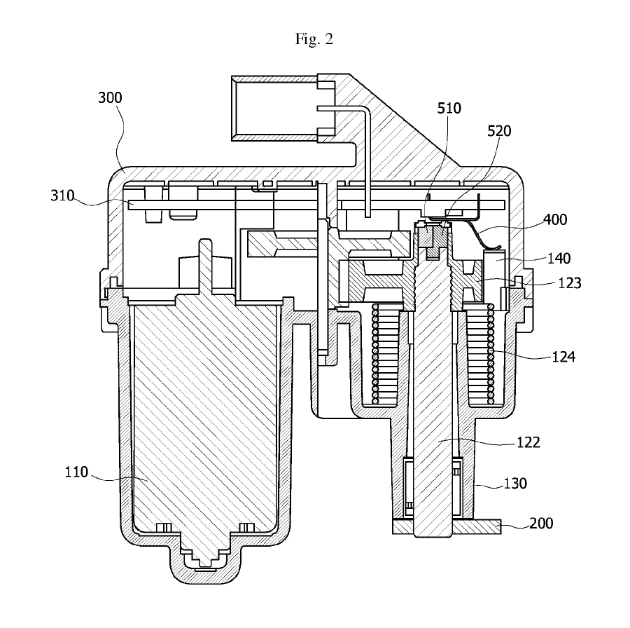

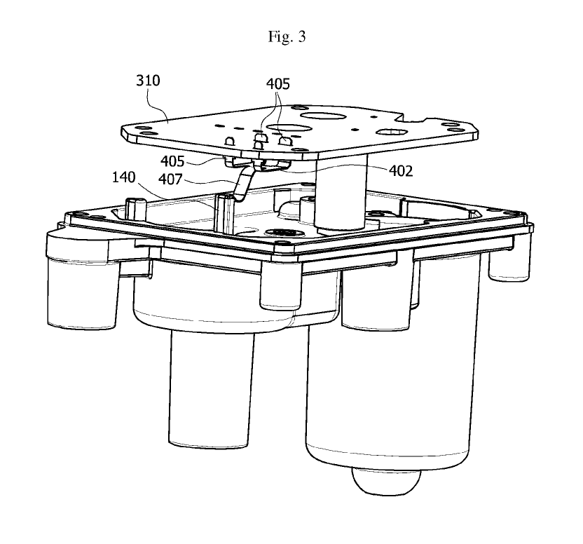

FIG. 1 is an exploded perspective view illustrating an electrical actuator for a variable geometry turbocharger according to an embodiment of the present invention, FIG. 2 is a cross-sectional view illustrating the electrical actuator for the variable geometry turbocharger illustrated in FIG. 1, and FIG. 3 is a partial perspective view illustrating the electrical actuator for the variable geometry turbocharger of FIG. 1.

In the electrical actuator for the variable geometry turbocharger of FIG. 1, an upper cover 300 is combined with an upper portion of a housing 100.

A deceleration gear part 121 is connected to an output side of a driving motor 110, and an output shaft 122 is connected to an output gear 123 of the deceleration gear part 121, thereby constituting a deceleration device 120.

A relatively larger torque than a torque generated in the driving motor 110 occurs in the deceleration device 120 connected to the driving motor 110.

A lever 200 is mounted on a bottom end of the output shaft 122 outside the housing 100.

The lever 200 operates due to the deceleration device 120, and the maximum operating angle of the lever 200 is 105° to 110°.

Also, the output shaft 122 is inserted in and penetrates an insertion hole 130 of the housing 100.

Housing protrusions 140 and 141 protrude from the periphery of the insertion hole 130, contact an extension part 127 of the output gear 123 and prevent rotation of the output gear 123.

The housing 100 includes a magnet 510 installed at one side of the output shaft 122 and a rotation angle detection sensor 520. The rotation angle detection sensor 520 measures a rotation angle of the output gear 123 using a change of flux of the magnet 510.

A ground structure 400 is installed between a printed circuit board 310 of the upper cover 300 and the housing 100 so as to prevent an electromagnetic interference (EMI) from occurring in the upper cover 300.

As an example of the ground structure 400, the ground structure 400 includes a flat panel part 402, insertion parts 405 that are upwardly refracted from the flat panel part 402, extend from the flat panel part 402 and are inserted in the printed circuit board 310, and an elastic part 407 that extends downwardly from the flat panel part 402 and has elasticity.

In more detail, the ground structure 400 is maintained by an elastic force when a part of four insertion parts 405 is inserted in and is fixed to the printed circuit board 310 and one elastic part 407 is mounted on the housing protrusion 140.

The ground structure 400 may be any one of an elastic body and a ground clip, and the elastic body may be any one of a leaf spring and a compression spring.

Thus, the ground structure having the above configuration can effectively reduce the EMI without including an additional filter unit.

Also, since the ground structure 400 is an elastic body or a ground clip, the ground structure 400 can contact and can be fixed to the upper cover 300 and the housing 100 more stably without shaking due to vibration of a vehicle.

A restoring spring 124 is connected to the output gear 123 and causes the lever 200 to be moved to an initial position of the lever 200 when the supply of power is stopped. The restoring spring 124 may be a torsion spring, a top end of the restoring spring 124 is hung in the hanging part 125 of the output gear 123, and a bottom end thereof is fixed to a bottom of the housing 100.

In this way, according to the present invention, the restoring spring 124 is connected to the output gear 123 and thus may cause the lever 200 connected to the output shaft 122 to be moved to the initial position of the lever 200 due to a restorative force when the supply of power is stopped. Thus, the efficiency of the driving motor 110 can be improved compared to the case that the output gear 123 is driven using only a driving force of the driving motor 110.

Also, according to the present invention, the housing protrusions 140 and 141 protrude from the periphery of the insertion hole 130 of the housing 100 and contact the extension part 127 of the output gear 123. Thus, the extension part 127 is rotated only between the housing protrusions 140 and 141 such that the lever 200 is rotated at an angle between the housing protrusions 140 and 141. Also, when the lever 200 is moved due to the restorative force of the restoring spring 124, the lever 200 can be moved to its initial position.

The ground structure 400 causes the upper cover 300 to be connected to the housing protrusion 140 so that the EMI can be reduced without including an additional filter unit. Also, the ground structure 400 does not constitute an additional protrusion for connecting an additional ground structure using the housing protrusion 140 that limits a rotation angle of the output gear 123 so that space occupancy can be improved.

Also, since the ground structure 400 is an elastic body or a ground clip, the ground structure 400 can contact and be fixed to the printed circuit board 310 and the housing protrusion 140 more stably without shaking due to vibration of the vehicle.

It will be apparent to those skilled in the art that various modifications can be made to the above-described exemplary embodiments of the present invention without departing from the spirit or scope of the invention. Thus, it is intended that the present invention covers all such modifications provided they come within the scope of the appended claims and their equivalents.

1. An electrical actuator for a variable geometry turbocharger, comprising:
a lever that is disposed outside a housing and is connected to a bottom end of an output shaft of a deceleration device; and
a ground structure that is installed between a printed circuit board and a housing protrusion so as to prevent an electromagnetic interference (EMI) from occurring.

2. The electrical actuator of claim 1, wherein the ground structure comprises a flat panel part, insertion parts that are upwardly refracted from the flat panel part and are inserted into the printed circuit board, and an elastic part that extends downwardly from the flat panel part and having elasticity, wherein a part of the insertion parts is inserted into and is fixed to the printed circuit board, and an end of the elastic body is mounted on a housing protrusion so that the ground structure is able to be maintained by an elastic force.

3. The electrical actuator of claim 1, wherein the ground structure is one of an elastic body and a group clip.

4. The electrical actuator of claim 3, wherein the elastic body is one of a leaf spring and a compression spring.

5. The electrical actuator of claim 1, wherein the housing further comprises an insertion hole in which the output shaft is inserted, and housing protrusions protrude from a periphery of the insertion hole and contact an extension part of an output gear so as to limit a rotation angle of the output gear.

6. The electrical actuator of claim 1, further comprising a restoring spring that is connected to the output gear of the deceleration device and causes the lever to be moved to an initial position of the lever when a supply of power is stopped.

7. The electrical actuator of claim 6, wherein the restoring spring is connected to the output gear and causes the lever to be moved to the initial position of the lever when the supply of power is stopped, and a top end of the restoring spring is hung in a hanging part of the output gear, and a bottom end of the restoring spring is fixed to a bottom of the housing.

8. The electrical actuator of claim 6, wherein the restoring spring is a torsion spring.

9. The electrical actuator of claim 1, wherein the housing further comprises a magnet installed at one side of the output shaft and a sensor, and the sensor measures a rotation angle of the output gear using a change of flux of the magnet.
